(19) United States
(12) Patent Application Publication
(10) Pub. No.: US 2011/0115067 A1
(43) Pub. Date: May 19, 2011

(54) SEMICONDUCTOR CHIP PACKAGE WITH MOLD LOCKS

(76) Inventor: Jen-Chung Chen, Taipei County (TW)

(21) Appl. No.: 12/710,367

(22) Filed: Feb. 23, 2010

Related U.S. Application Data
(63) Continuation-in-part of application No. 12/620,601, filed on Nov. 18, 2009.

(51) Int. Cl. H01L 23/31

(52) U.S. Cl. 257/690; 257/787; 257/E23.123

(57) ABSTRACT

A semiconductor chip package includes a base comprising a die attach region and a mold-lock forming region surrounding the die attach region; a die mounted onto the base within the die attach region; a plurality of line-shaped trenches in the mold-lock forming region; a mold body encapsulating the die; and a mold lock inlaid in each of the line-shaped trenches to securely interlock the mold body to the base.

### CROSS REFERENCE TO RELATED APPLICATIONS

The application is a continuation-in-part of U.S. application Ser. No. 12/620,601 filed Nov. 18, 2009, which is included in its entirety herein by reference.

### BACKGROUND OF THE INVENTION

1. Field of the Invention

This invention relates generally to semiconductor packaging, and more specifically, to a semiconductor chip package with mold locks, which anchor the molding material and prevent molding material from de-lamination.

2. Description of the Prior Art

In a conventional method for chip package, at least a die are electrically connected and mechanically bonded to a base. Typically, the die is encapsulated in a plastic molding compound in order to protect it from exposure to moisture or any contaminant during processing.

However, mechanical stress can be built up between layers of the plastic molding compound and the base while in packaging process. Such stress typically stems from the mismatch between the coefficient of thermal expansion (CTE) of the plastic molding compound and of the base. The CTE of the mold compound is typically a mismatch to the integrated circuit.

During packaging process operation, the chip goes through cycles of heating and cooling and may encounter brief thermal shocks. These heating and cooling cycles stress the chip package during expansion and contraction of different materials of the package. The stresses placed on the package during brief thermal shocks are significant, leading to weakened packages and immediate, catastrophic failure or defect such as so-called de-lamination. When the plastic molding compound delaminates from the base, the moisture may penetrate into the package molding compound, resulting in chip failure. Furthermore, de-lamination can damage the metal bonding wires that couple the base to the die.

It therefore becomes highly desirable to develop a package structure to prevent de-lamination, while preserve the integrity of the chip package.

### SUMMARY OF THE INVENTION

According to a preferred embodiment of the present invention, a semiconductor chip package includes a base comprising a top surface and a bottom surface, the top surface comprising a die attach region and a mold-lock forming region surrounding the die attach region, a die attached on the die attach region, a molding material encapsulating the die and a plurality of through holes filled up with the molding material formed in the mold-lock forming region.

According to another preferred embodiment of the present invention, a mold lock for a semiconductor chip package includes: a molding material with a tapered profile inlaid into an outer edge of a base.

According to another preferred embodiment of the present invention, a mold lock for a semiconductor chip package, includes: a molding material inlaid into an outer edge of a base, wherein the molding material has a mold bump protruding from a bottom surface of the base.

The mold locks of the preferred embodiment of the present invention work like anchors to interlock the entire molding material on the base and prevent de-lamination between the base and the molding material.

From another aspect of this invention, a semiconductor chip package includes a base comprising a die attach region and a mold-lock forming region surrounding the die attach region; a die mounted onto the base within the die attach region; a plurality of line-shaped trenches in the mold-lock forming region; a mold body encapsulating the die; and a mold lock inlaid in each of the line-shaped trenches to securely interlock the mold body to the base.

From still another aspect of this invention, a semiconductor chip package includes a base comprising a die attach region and a mold-lock forming region surrounding the die attach region; a die mounted onto the base within the die attach region; a plurality of serpentine trenches in the mold-lock forming region; a mold body encapsulating the die; and a mold lock inlaid in each of the serpentine trenches to securely interlock the mold body to the base.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a top view of a semiconductor chip package with mold locks.

FIG. 2 is a schematic, sectional view of a semiconductor chip package with mold locks taken along line A-A′ of FIG. 1.

FIG. 3 is a schematic, sectional view of a semiconductor chip package with mold locks taken alone line B-B′ of FIG. 1

FIG. 4 schematically depicts a variant of the mold lock structure.

FIG. 5 depicts a variant of the arrangement of the mold locks.

FIG. 6 depicts a schematic, sectional view of a semiconductor chip package with mold locks according to the second embodiment of the present invention taken along line A-A′ of FIG. 1.

FIG. 7 is another schematic, sectional view of a semiconductor chip package with mold locks taken alone line A-A′ of FIG. 1 according to the second embodiment of the present invention

FIG. 8 depicts a mold for fabricating the mold body and the mold locks in FIG. 2.

FIG. 9 depicts a mold for fabricating the mold body and the mold locks in FIG. 6.

FIG. 10 schematically depicts a top view of a semiconductor chip package with mold locks in accordance with another embodiment of this invention.

FIG. 11 is a schematic, sectional view of a semiconductor chip package with mold locks taken alone line A-A′ of FIG. 10.

FIG. 12 schematically depicts a top view of a semiconductor chip package with mold locks in accordance with still another embodiment of this invention

### DETAILED DESCRIPTION

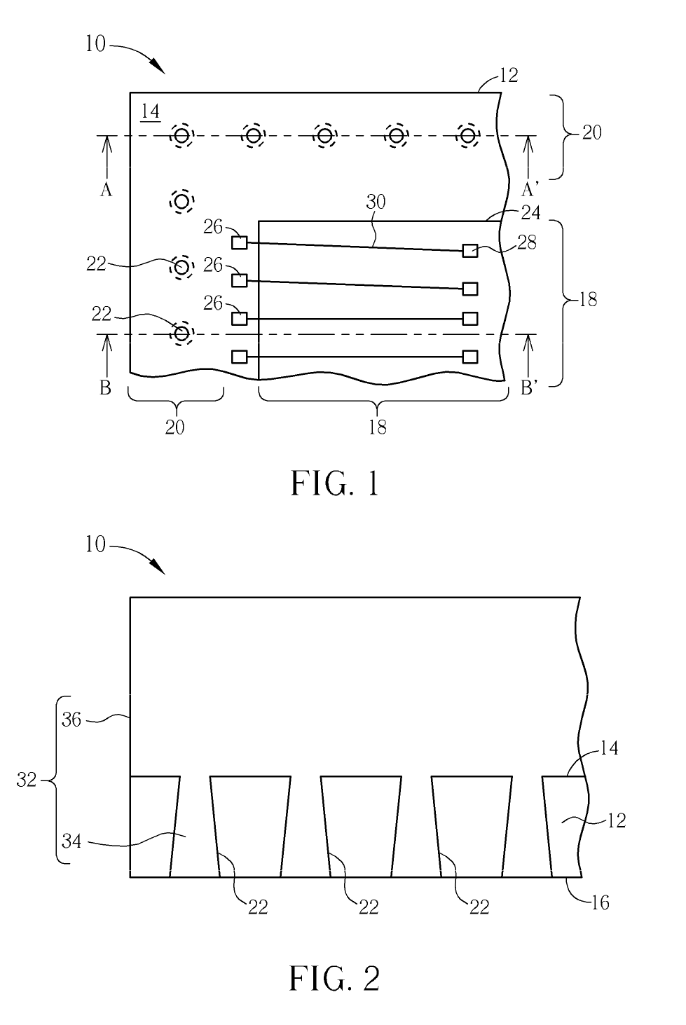

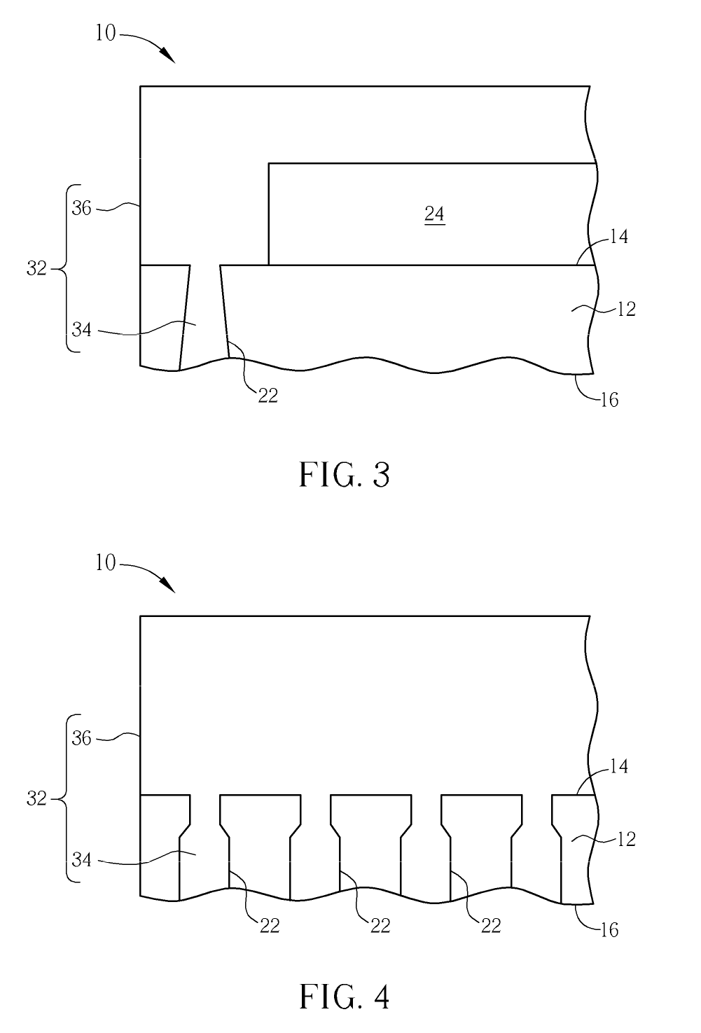

FIG. 1 schematically depicts a top view of a semiconductor chip package with mold locks. FIG. 2 is a schematic, sectional view of a semiconductor chip package with mold locks taken alone line A-A′ of FIG. 1 according to the first embodiment of the present invention. FIG. 3 is a schematic, sectional view of a semiconductor chip package with mold locks taken alone line B-B′ of FIG. 1. FIG. 4 depicts a variant of mold locks.

As shown in FIG. 1, FIG. 2 and FIG. 3, a semiconductor chip package 10 includes a base 12 having a top surface 14 and a bottom surface 16. For example, the base 12 may be a packaging substrate. The top surface 14 includes a die attach region 18 and a mold-lock forming region 20. The mold-lock forming region 20 is defined as the outer periphery area of surrounding the die attach region 18 at the base 12. A plurality of through holes 22 are formed in the mold-lock forming region 20, and a die 24 is mounted on the top surface 14 of the base 12 within the die attach region 18. According to the first embodiment of the present invention, the through holes 22 may be aligned with each other along a respective side edge of the base 12.

The semiconductor chip package 10 further includes a plurality of base conducting pads 26 disposed on the top surface 14. According to the first embodiment of the present invention, the base conducting pads 26 are arranged between the die attach region 18 and the mold-lock forming region 20. A plurality of die conducting pads 28 are provided on the die 24. A bond wire 30 extending between one of the die conducting pads 28 and one of the base conducting pads 26 is provided to electrically connect the die 24 to the base 12.

It is noteworthy that the semiconductor chip package 10 has a molding material 32 encapsulating the die 24 and filling up the through holes 22. The molding material 32 filling into the through holes 22 anchors the molding material 32 to the base 12. The molding material 32 filling up the through holes 22 is hereinafter referred to as mold locks 34 inlaid into the mold-lock forming region 20 of the base 12. The molding material 32 encapsulating the die 24 is hereinafter referred to as a mold body 36. The mold locks 34 interlock the mold body 36 to the base 12.

Each of the through holes 22 has a tapered profile broadening from the top surface 14, and each of the mold locks 34 is therefore shaped by the tapered profile of the corresponding through hole 22. As can be best seen in FIG. 2, the tapered profile of each through hole 22 is analogous to a frustum cone.

As shown in FIG. 4, the tapered profile of each through hole 22 can be a bottle-like shape. Of course, other shapes with a bottom surface larger than a top surface can be used as the profile of the through holes 22.

Since the tapered profile of through holes 22 has a widened bottom, the mold body 36 is tightly anchored onto the base 12 through the mold locks 34. Furthermore, the mold body 36 and the mold locks 34 constitute an integral and monolithic structure. The mold locks 34 have adequate strength to interlock the mold body 36 to the base 12. Accordingly, the de-lamination of the mold body 36 from the base 12 can be prevented.

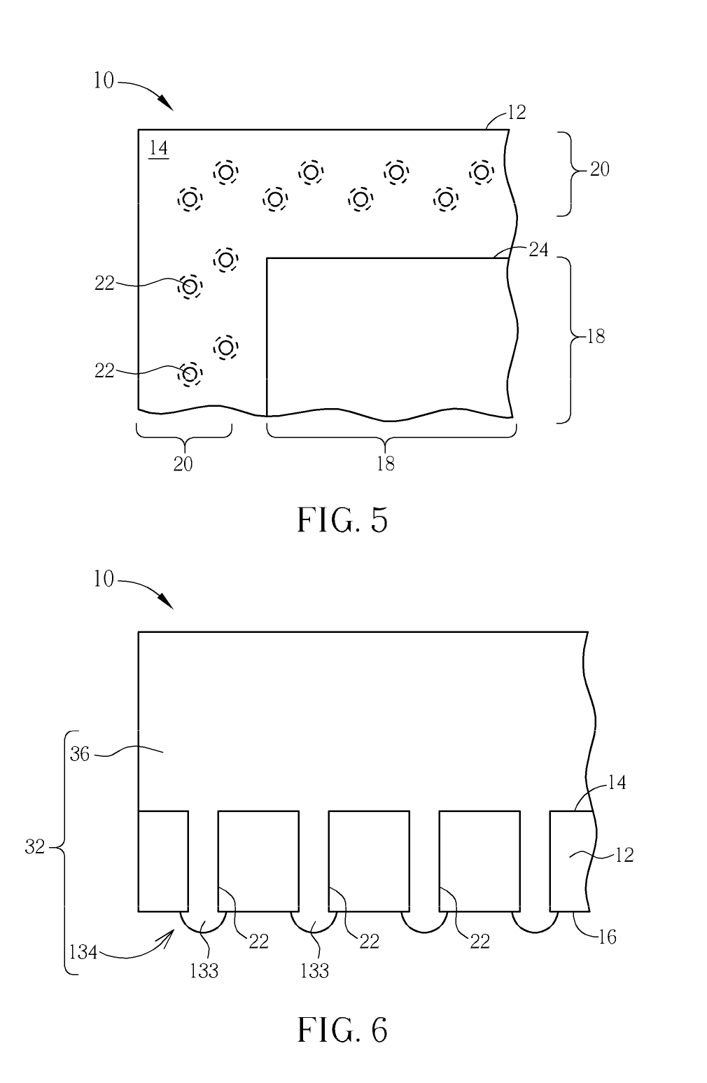

FIG. 5 depicts a variant of the arrangement of the mold locks. Although the through holes 22 are arranged aligned with each other along each side edge of the base 12 in FIG. 1, as shown in FIG. 5, the through holes 22 can be arranged in a staggered fashion.

FIG. 6 is a schematic, sectional view of a semiconductor chip package with mold locks taken alone line A-A′ of FIG. 1 according to the second embodiment of the present invention, wherein like elements, layers or regions are designated with like numeral numbers.

One difference between the semiconductor chip package in the first embodiment of FIG. 2 and the semiconductor chip package in the second embodiment of FIG. 6 is the shape of the mold locks. Other elements of FIG. 6 are generally in the same position and has the same function as those depicted in FIG. 2. Please refer to the previous description of FIG. 1 to FIG. 4 for reference.

As shown in FIG. 6, a semiconductor chip package 10 has a molding material 32 encapsulating a die 24, filling up the through holes 22 and forming a plurality of mold bumps 133 protruding from the bottom surface 16 of the base 12. Each of the mold bumps 133 integrates with the molding material 32 in each of the through holes 22. The molding material 32 filling up the through holes 22 and the mold bumps 133 together function as mold locks 134.

The mold locks 134 are inlaid into the mold-lock forming region 20. The mold locks 134 anchor the mold body 36 to the base 12.

Preferably, each of the through holes 22 has a cylinder-shaped sectional profile, however, this invention should not be limited to such cylinder-shaped sectional profile. Other shapes or sectional profiles of the through holes 22 can be applied. Advantageously, each of the mold bumps 133 is spherical shaped. The protruding mold bumps 133 can increase the interlocking between the mold body 36 and the base 12.

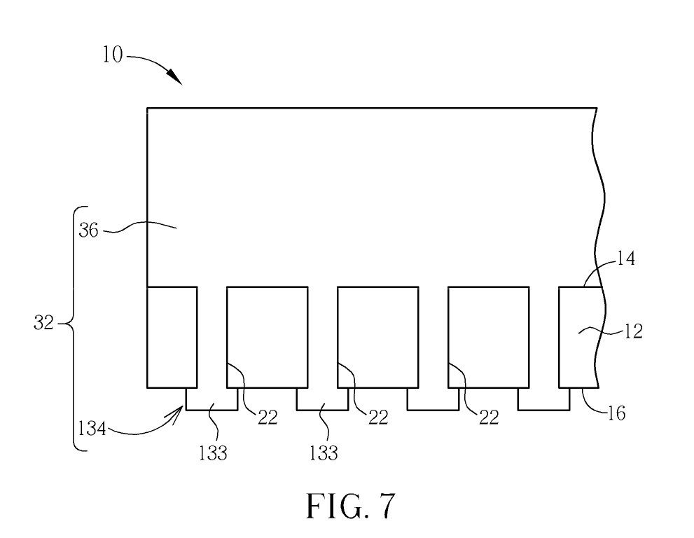

FIG. 7 depicts a variant of mold locks according to the second embodiment of the present invention. The elements with the same function are designated with the same numeral references in FIG. 6. Although each of the mold bump 133 is spherical shaped in FIG. 6, as shown in FIG. 7, each of the mold bump 133 can also be cubic shaped. Alternatively, other shapes such as a spheroid or hexagonal solid can be utilized as the shape of the mold bump 133 according to the present invention.

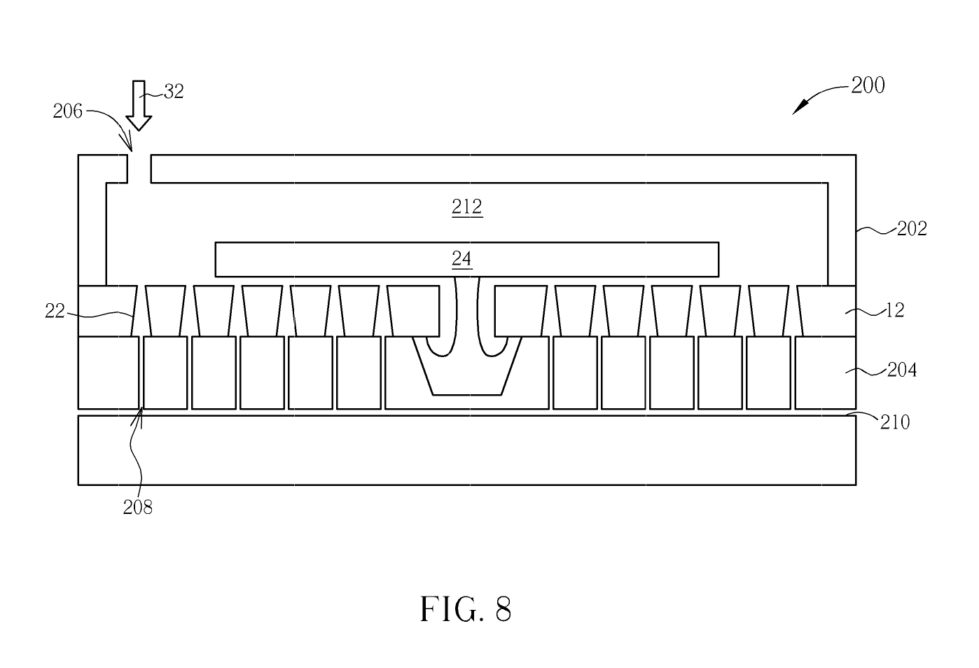

FIG. 8 depicts a mold for fabricating the mold body and the mold locks in FIG. 2. The same elements with the same function will be designated with the same numeral references in FIG. 2.

As shown in FIG. 8, a mold 200 includes an upper mold 202 and a lower mold 204. The upper mold 202 has an inlet 206 disposed on the upper mold 202. The lower mold 204 has a plurality of first vents 208, and each of the first vents 208 is disposed corresponding to a through hole 22 of the base 12. The lower mold 204 further includes a second vent 210 which connects to each of the first vents 208. During a molding process, such as transfer mold or compression mold, the upper mold 202 and the lower mold 204 are pressed to each other together, the base 12 and the die 24 are sandwiched between the upper mold 202 and the lower mold 204, and a chamber 212 is created between the upper mold 202 and the package 10.

After that, the molding material 32 is injected into the chamber 212. When the molding material 32 flows into the through holes 22, the air inside the through holes 22 is pressed out through the first vents 208 and the second vent 210 by the molding material 32. Therefore, the molding material 32 can completely fills up the through holes 22 without air trapped inside of the molding material 32. Finally, after the molding material 32 fills up the chamber 212, the molding material 32 is cured and the desired mold body 36 and mold locks 34 in FIG. 2 is thus formed.

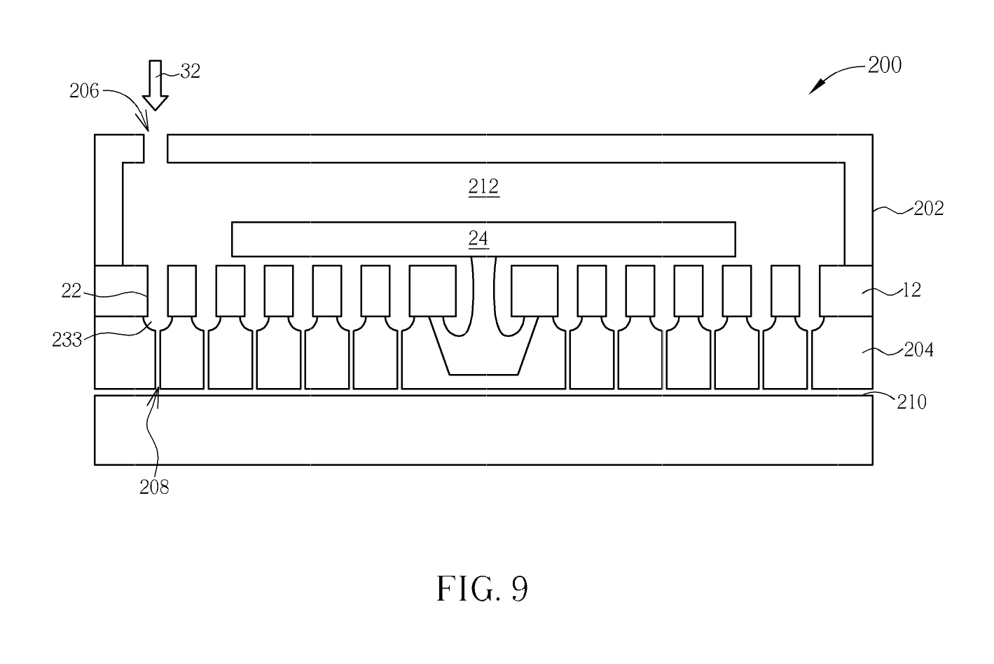

FIG. 9 depicts a mold for fabricating the mold body and the mold locks in FIG. 6. The same elements with the same function will be designated with the same numeral references in FIG. 6 and FIG. 8.

The primary difference between the mold in FIG. 8 and FIG. 9 is that the lower mold 204 in FIG. 9 has mold bump cavities for the formation of the mold bumps in FIG. 6.

Please refer to FIG. 9, a mold 200 includes an upper mold 202 and a lower mold 204. The upper mold 202 has an inlet 206 disposed on the upper mold 202. The lower mold 204 has a plurality of mold bump cavities 233 disposed corresponding to each of the through hole 22 for forming the mold bumps 133. Each of the mold bump cavities 233 communicates with one end of a first vent 208. The other end of each of the first vent 208 is connected to a second vent 210.

During a molding process, a chamber 212 is formed between the upper mold 202 and the base 12, and the upper mold 202 the die 24. After that, the molding material 32 is injected into the chamber 212. The molding material is pressed into the through holes 22 first, and then flows into the mold bump cavities 233. The air inside the through holes 22 and the mold bump cavities 233 is pressed out through the first vents 208 and the second vent 210 by the molding material 32. Finally, after the molding material 32 fills up the chamber 212, the molding material 32 is cured. A semiconductor chip package with mold locks is formed.

Although only spherical shaped mold bump cavities 233 is shown in FIG. 9, other shapes of the mold bump cavities 233 such as cubic shaped can be applied.

Since the mold locks and the mold body are formed by the molding material, and cured simultaneously, the mold locks and the mold body is an integral and monolithic structure. Therefore, the mold locks can provide adequate strength to affix the mold body to the base. Furthermore, to form the mold locks, only some vent holes are need to be formed on the mold. The fabricating steps for forming the chip package having mold locks are compatible with the conventional packaging and molding process.

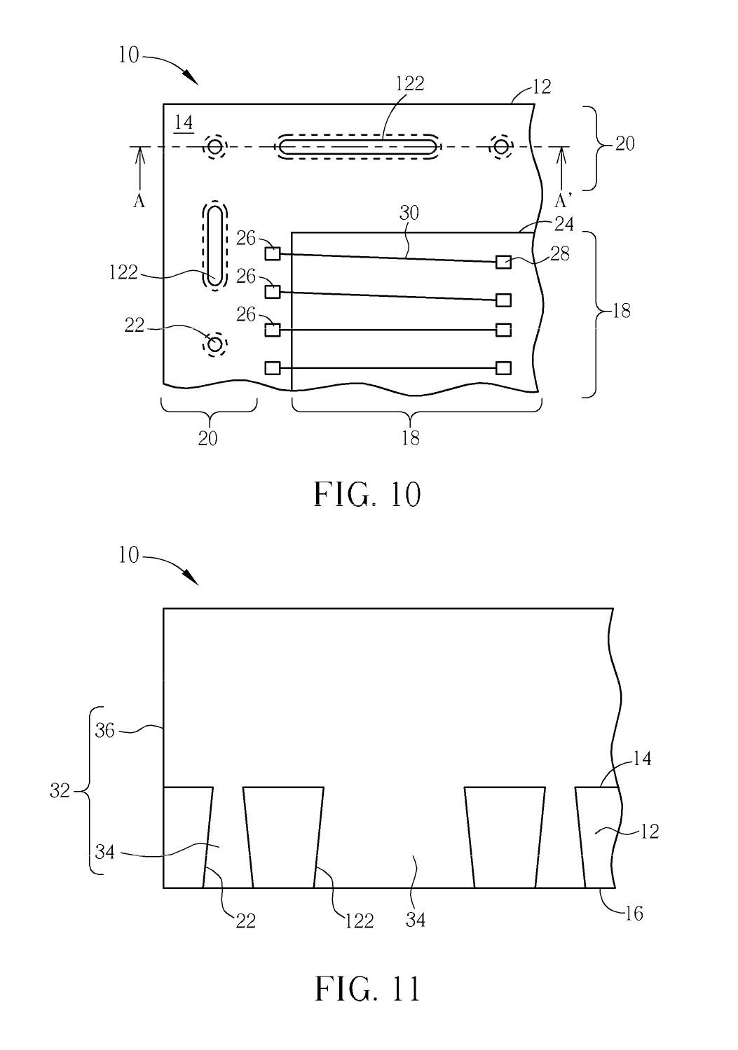

FIG. 10 schematically depicts a top view of a semiconductor chip package with mold locks in accordance with another embodiment of this invention. FIG. 11 is a schematic, sectional view of a semiconductor chip package with mold locks taken alone line A-A′ of FIG. 10.

As shown in FIG. 10 and FIG. 11, likewise, a semiconductor chip package 10 includes a base 12 having a top surface 14 and a bottom surface 16. For example, the base 12 may be a packaging substrate. The top surface 14 includes a die attach region 18 and a mold-lock forming region 20. The mold-lock forming region 20 is defined as the outer periphery area of the base 12 and it surrounds the die attach region 18. A plurality of through holes 22 are provided in the mold-lock forming region 20, and a die 24 is mounted on the top surface 14 of the base 12 within the die attach region 18. According to this embodiment, the through holes 22 may include discontinuous line-shaped trenches 122.

The semiconductor chip package 10 may further include a plurality of base conducting pads (or bond fingers) 26 disposed on the top surface 14. The base conducting pads 26 may be arranged between the die attach region 18 and the mold-lock forming region 20. A plurality of die conducting pads (or input/output pads) 28 are provided on the die 24. A bond wire 30 extending between one of the die conducting pads 28 and one of the base conducting pads 26 is provided to electrically connect the die 24 to the base 12. It is to be understood that the present invention should not be limited to the wire-bonding configuration as described above, and the present invention is also suited for any other types of chip packages such as flip-chip packages.

As best seen in FIG. 11, the semiconductor chip package 10 further includes a molding material 32 that encapsulates the die 24 and fills up the through holes 22 as well as the line-shaped trenches 122. The molding material 32 filling into the through holes 22 and the line-shaped trenches 122 forms mold locks 34 inlaid into the mold-lock forming region 20 of the base 12, which anchor the molding material 32 to the base 12. The mold locks 34 securely interlock the mold body 36 to the base 12.

Preferably, each of the through holes 22 and line-shaped trenches 122 has a tapered profile broadening from the top surface 14, and each of the mold locks 34 is therefore shaped by the tapered profile of the corresponding through hole 22 and line-shaped trenches 122. In addition, the tapered profile of each of the through holes 22 and line-shaped trenches 122 can be a bottle-like shape. Of course, other shapes with a bottom surface larger than a top surface can be used.

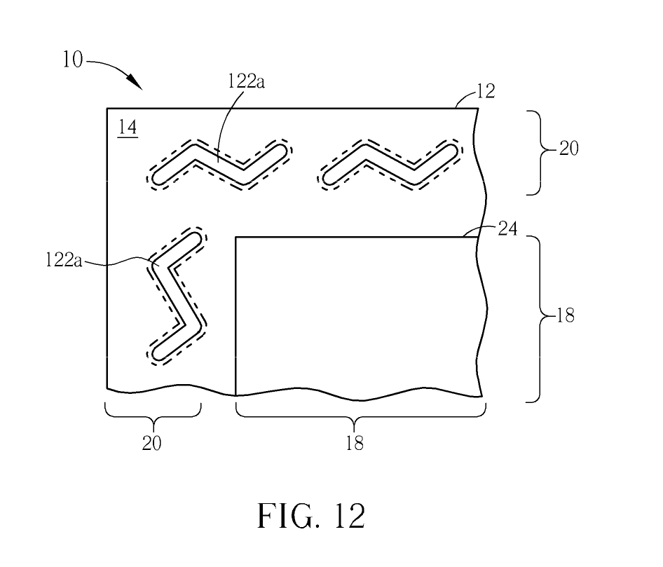

FIG. 12 schematically depicts a top view of a semiconductor chip package with mold locks in accordance with still another embodiment of this invention. As shown in FIG. 12, the difference between the semiconductor chip package of FIG. 10 and the semiconductor chip package of FIG. 12 is that the through holes formed in the mold-lock forming region 20 of FIG. 12 include discontinuous, serpentine trenches 122a. It is to be understood that the present invention should not be limited to the wire-bonding configuration as described above, and the present invention is also suited for any other types of chip packages such as flip-chip packages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor chip package, comprising:
a base comprising a die attach region and a mold-lock forming region surrounding the die attach region;
a die mounted onto the base within the die attach region;
a plurality of line-shaped trenches in the mold-lock forming region;
a mold body encapsulating the die; and
a mold lock inlaid in each of the line-shaped trenches to securely interlock the mold body to the base.

2. The semiconductor chip package of claim 1, wherein each of the line-shaped trenches has a tapered cross-section profile.

3. The semiconductor chip package of claim 1 further comprising a plurality of die conducting pads disposed on the die.

4. The semiconductor chip package of claim 3 further comprising a plurality of base conducting pads disposed between the die attach region and the mold-lock forming region, and a plurality of bone wires extending between the plurality of die conducting pads and the plurality of base conducting pad.

5. The semiconductor chip package of claim 1, wherein the mold-lock forming region is a periphery area along the edges of the die on the base.

6. The semiconductor chip package of claim 1, wherein the line-shaped trenches are discontinuous.

7. A semiconductor chip package, comprising:
a base comprising a die attach region and a mold-lock forming region surrounding the die attach region;
a die mounted onto the base within the die attach region;
a plurality of serpentine trenches in the mold-lock forming region;
a mold body encapsulating the die; and
a mold lock inlaid in each of the serpentine trenches to securely interlock the mold body to the base.

8. The semiconductor chip package of claim 7, wherein each of the serpentine trenches has a tapered cross-section profile.

9. The semiconductor chip package of claim 7 further comprising a plurality of die conducting pads disposed on the die.

10. The semiconductor chip package of claim 9 further comprising a plurality of base conducting pads disposed between the die attach region and the mold-lock forming region, and a plurality of bone wires extending between the plurality of die conducting pads and the plurality of base conducting pad.

11. The semiconductor chip package of claim 7, wherein the mold-lock forming region is a periphery area along the edges of the die on the base.

12. The semiconductor chip package of claim 7, wherein the serpentine trenches are discontinuous.
